(19) United States
(12) Patent Application Publication
(10) Pub. No.: US 2026/0271428 A1
(43) Pub. Date: Sep. 10, 2026

(54) FLIP CHIP PHOTODIODE AND MANUFACTURING METHOD THEREOF

(71) Applicant: Taiwan-Asia Semiconductor Corporation, Hsinchu City (TW)

(72) Inventor: Ching-Pu Tai, Hsinchu City (TW)

(21) Appl. No.: 19/279,016

(22) Filed: Jul. 24, 2025

(30) Foreign Application Priority Data
Mar. 10, 2025 (TW) 114108635

(51) Int. Cl. H10F 77/30; H10F 30/223; H10F 71/00; H10F 77/124; H10F 77/40

(52) U.S. Cl. CPC H10F 77/334; H10F 30/223; H10F 71/1272; H10F 77/1248; H10F 77/306; H10F 77/337; H10F 77/413

(57) ABSTRACT

A flip-chip photodiode and a manufacturing method thereof are provided. The flip-chip photodiode comprises a mesa epitaxial layer, a second conductive type epitaxial layer, a transparent substrate, and an optical bonding layer. The mesa epitaxial layer has a laser-sintered sidewall arranged to be disposed on an outer periphery of the mesa epitaxial layer. The second conductive type epitaxial layer is disposed on the mesa epitaxial layer, and the optical bonding layer bonds the transparent substrate to the second conductive type epitaxial layer. When external light enters the optical bonding layer through the transparent substrate, only a light with a specific waveband of the external light is allowed to pass therethrough, and other light of the external light other than the specific waveband is blocked.

### CROSS-REFERENCES TO RELATED APPLICATIONS

This application claims the benefit of priority to Taiwanese Patent Application No. 114108635 filed on Mar. 10, 2025, which is hereby incorporated by reference in its entirety.

### BACKGROUND OF THE INVENTION

### Field of the Invention

This invention relates to a flip-chip photodiode and a manufacturing method thereof, and in particular to a flip-chip photodiode with high integration, high structural strength, and high signal-to-noise ratio and a manufacturing method thereof.

### Descriptions of the Related Art

A photodiode is an electronic device that converts external optical signals into electrical signals. Its core function is to absorb external light for detecting optical signals and converting them into measurable electrical current. This conversion is critical for various applications, such as optical communication, optical measurement, and image generation.

The mechanism by which a photodiode absorbs external light involves the semiconductor material (e.g., silicon substrate) within the diode absorbing light. When photons enter the photodiode and are absorbed, the energy of the photons can cause electrons in the valence band to transition to the conduction band for generating electron-hole pairs. These photo-generated carriers are separated under the influence of the built-in electric field within the diode for producing an electric current.

However, traditional photodiodes face two issues. First, the material structure of traditional short-wave infrared (SWIR) photodiodes, with a spectral range of 0.9 to 1.7 micrometers, is typically grown layer-by-layer on an indium phosphide (InP) substrate. However, the InP substrate material is very fragile, making it highly susceptible to breakage during the wafer fabrication process, thereby affecting yield rates and resulting in high manufacturing costs, which are difficult to meet the requirements of economical mass production. On the other hand, due to the spatial constraints of metal interconnects in the traditional vertical structure design, the size and volume of traditional photodiode devices can no longer meet the miniaturization demands of next-generation devices, thereby impacting the application design of back-end modules. To overcome these issues, there is an urgent need in the industry for an innovative photodiode architecture that not only addresses the insufficient structural strength of the aforementioned photodiode wafers but also overcomes issues such as poor integration and low signal-to-noise ratio caused by the excessive volume of photodiodes.

### SUMMARY OF THE INVENTION

The primary objective of this invention is to provide an innovative flip-chip photodiode and a manufacturing method thereof. Compared to traditional photodiodes, the photodiode of this invention employs wafer transfer and bonding technology to transfer the epitaxial structure of the photodiode from a fragile epitaxial growth substrate to a high-strength transparent substrate, thereby enhancing the structural strength of the wafer body, improving process yield rates, reducing production costs, and meeting the requirements of economical production. Simultaneously, on the other hand, by utilizing wafer transfer and bonding technology, the vertical structure of traditional photodiodes is transformed into a flip-chip structure, thereby altering the metal pad structure of the wafer, increasing the integration of wafers in modules, and aligning with the trend of wafer miniaturization. More particularly, this invention further utilizes laser sintering technology to form laser-sintered sidewalls within the device structure to effectively block external light interference from the device sidewalls, thereby suppressing noise interference and improving the signal-to-noise ratio (SNR) and photocurrent gain effect of the device.

To achieve the above objective, this invention provides a flip-chip photodiode comprising a mesa epitaxial layer, a second conductive type epitaxial layer, a transparent substrate, and an optical bonding layer. The mesa epitaxial layer has an intrinsic epitaxial layer, a first conductive type in-situ doped epitaxial layer, and a laser-sintered sidewall. The intrinsic epitaxial layer is disposed on the first conductive type in-situ doped epitaxial layer, and the laser-sintered sidewall is disposed on an outer periphery of the first conductive type in-situ doped epitaxial layer to substantially block external light from entering the first conductive type in-situ doped epitaxial layer through the laser-sintered sidewall. The second conductive type epitaxial layer is disposed on the mesa epitaxial layer, and the optical bonding layer bonds the transparent substrate to the second conductive type epitaxial layer. When external light enters the optical bonding layer through the transparent substrate, only a light with a specific waveband of the external light is allowed to pass therethrough, and other light of the external light other than the specific waveband is blocked.

In one embodiment of the flip-chip photodiode of this invention, the laser-sintered sidewall is further disposed in the intrinsic epitaxial layer.

In one embodiment of the flip-chip photodiode of this invention, the first conductive type in-situ doped epitaxial layer is an N-type in-situ doped indium phosphide (InP) epitaxial layer, with a dopant selected from one of sulfur (S) or silicon (Si), and a doping concentration of 10¹⁷ to 10¹⁹ cm⁻³.

In one embodiment of the flip-chip photodiode of this invention, the photodiode further comprises a reflector covering a surface and a sidewall of the mesa epitaxial layer to block external light from entering the mesa epitaxial layer.

In one embodiment of the flip-chip photodiode of this invention, the reflector is a distributed Bragg reflector (DBR) layer.

In one embodiment of the flip-chip photodiode of this invention, the photodiode further comprises a first metal ring disposed on the surface of the first conductive type in-situ doped epitaxial layer inside the laser-sintered sidewall and partially covered by the reflector.

In one embodiment of the flip-chip photodiode of this invention, the photodiode further comprises a second metal ring disposed adjacent to the sidewall of the mesa epitaxial layer and electrically connected to the second conductive type epitaxial layer.

In one embodiment of the flip-chip photodiode of this invention, the optical bonding layer is a multi-channel band-pass filter (MBPF) layer configured to allow the light with the specific waveband of the external light to pass therethrough.

In one embodiment of the flip-chip photodiode of this invention, the optical bonding layer further comprises an anti-reflection (AR) layer configured to reduce surface reflection loss of the optical bonding layer.

In one embodiment of the flip-chip photodiode of this invention, the transparent substrate further comprises a passivation layer configured to bond the optical bonding layer, thereby bonding the transparent substrate to the second conductive type epitaxial layer.

In one embodiment of the flip-chip photodiode of this invention, the passivation layer is selected from the group consisting of silicon oxide, titanium oxide, and combinations thereof.

To achieve the above objective, this invention provides a manufacturing method for a flip-chip photodiode, comprising the following steps. First, provide an epitaxial growth substrate and sequentially grow a first conductive type in-situ doped epitaxial layer, an intrinsic epitaxial layer, and a second conductive type epitaxial layer on the epitaxial growth substrate. Next, provide an optical bonding layer on the second conductive type epitaxial layer. Then, bond a transparent substrate to the optical bonding layer and remove the epitaxial growth substrate. Provide a laser-sintered sidewall disposed on an outer periphery of the first conductive type in-situ doped epitaxial layer. Remove portions of the first conductive type in-situ doped epitaxial layer and the intrinsic epitaxial layer to form a mesa epitaxial layer. Finally, provide a reflector covering the surface and the sidewall of the mesa epitaxial layer.

In one embodiment of the manufacturing method of the flip-chip photodiode of this invention, the step of providing a laser-sintered sidewall is to provide a laser to form the laser-sintered sidewall disposed on the outer periphery of the first conductive type in-situ doped epitaxial layer and in the intrinsic epitaxial layer.

In one embodiment of the manufacturing method of the flip-chip photodiode of this invention, the step of providing a first conductive type in-situ doped epitaxial layer is to provide an N-type in-situ doped indium phosphide (InP) epitaxial layer.

In one embodiment of the manufacturing method of the flip-chip photodiode of this invention, the step of providing an N-type in-situ doped indium phosphide (InP) epitaxial layer is to perform indium phosphide (InP) epitaxial growth using metal-organic chemical vapor deposition (MOCVD) while simultaneously doping with one of sulfur (S) or silicon (Si), with a doping concentration of 10¹⁷ to 10¹⁹ cm⁻³.

In one embodiment of the manufacturing method of the flip-chip photodiode of this invention, the step of providing a reflector is to provide a distributed Bragg reflector layer.

In one embodiment of the manufacturing method of the flip-chip photodiode of this invention, the method further comprises a step of providing a first metal ring after providing the laser-sintered sidewall, wherein the first metal ring is disposed on the surface of the first conductive type in-situ doped epitaxial layer inside the laser-sintered sidewall.

In one embodiment of the manufacturing method of the flip-chip photodiode of this invention, the method further comprises providing a second metal ring disposed adjacent to the sidewall of the mesa epitaxial layer and electrically connected to the second conductive type epitaxial layer.

In one embodiment of the manufacturing method of the flip-chip photodiode of this invention, the step of providing an optical bonding layer is to provide a multi-channel band-pass filter layer configured to allow a light with a specific waveband of the external light to pass therethrough.

In one embodiment of the manufacturing method of the flip-chip photodiode of this invention, the step of providing an optical bonding layer further comprises providing an anti-reflection layer configured to reduce surface reflection loss of the optical bonding layer.

After referring to the drawings and the embodiments as described in the following, those the ordinary skilled in this art can understand other objectives of the present invention, as well as the technical means and embodiments of the present invention.

### BRIEF DESCRIPTION OF THE DRAWINGS

FIG. 1 to FIG. 10 are cross-sectional schematic diagrams illustrating the manufacturing process of a flip-chip photodiode in one embodiment of this invention; and

FIG. 11 is a flowchart schematic diagram of the process steps of a flip-chip photodiode in one embodiment of this invention.

### DETAILED DESCRIPTION OF THE PREFERRED EMBODIMENT

In the following description, the present invention will be explained with reference to various embodiments thereof. These embodiments of the present invention are not intended to limit the present invention to any specific environment, application or particular method for implementations described in these embodiments. Therefore, the description of these embodiments is for illustrative purposes only and is not intended to limit the present invention. It shall be appreciated that, in the following embodiments and the attached drawings, a part of elements not directly related to the present invention may be omitted from the illustration, and dimensional proportions among individual elements and the numbers of each element in the accompanying drawings are provided only for ease of understanding but not to limit the present invention.

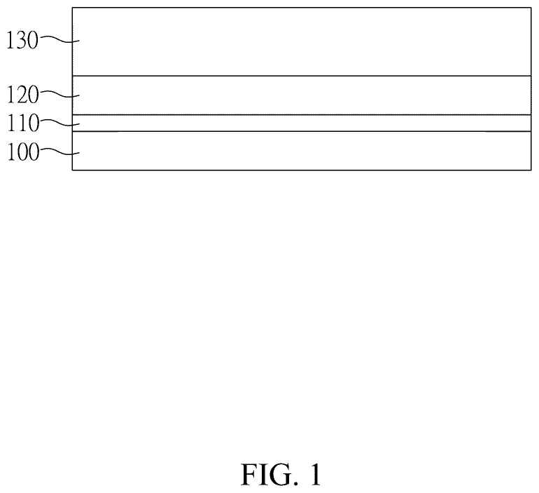

Please refer to FIG. 1 to FIG. 10, which illustrate cross-sectional schematic diagrams of the manufacturing process of a flip-chip photodiode in one embodiment of this invention. Specifically, this flip-chip photodiode is a compound semiconductor flip-chip photodiode. In this embodiment, the manufacturing of the flip-chip photodiode 10 begins with epitaxially growing an ohmic-contact epitaxial layer 110 on an epitaxial growth substrate 100, serving as a layer for forming ohmic contact with a metal layer in subsequent metal interconnect processes. Specifically, the epitaxial growth substrate 100 may be, but is not limited to, an indium phosphide (InP) substrate. The ohmic-contact epitaxial layer 110 may be, but is not limited to, an indium gallium arsenide (InGaAs) epitaxial layer.

Next, as shown in FIG. 1, a first conductive type in-situ doped epitaxial layer 120 and an intrinsic epitaxial layer 130 are sequentially epitaxially grown on the ohmic-contact epitaxial layer 110. Specifically, the first conductive type in-situ doped epitaxial layer 120 is an N-type doped epitaxial layer formed using metal-organic chemical vapor deposition (MOCVD), such as, but not limited to, doping with one of sulfur (S) or silicon (Si) during the epitaxial growth of an indium phosphide (InP) epitaxial layer, with a doping concentration of approximately 10¹⁷ to 10¹⁹ cm⁻³, to establish an appropriate built-in electric field for driving electron drift. Furthermore, the intrinsic epitaxial layer 130 may be an indium gallium arsenide (InGaAs) epitaxial layer disposed on the first conductive type in-situ doped epitaxial layer 120, with a low doping concentration of approximately 10¹⁴ to 10¹⁵ cm⁻³, ensuring a long carrier drift distance, preventing carrier recombination within the intrinsic epitaxial layer, and effectively enabling electron-hole separation and drift for improving photoresponse efficiency. It should be noted that, due to the uniform doping distribution formed by the “in-situ doping” process in the first conductive type in-situ doped epitaxial layer 120 of this invention, the photoresponse efficiency and current gain of the photodiode can be enhanced.

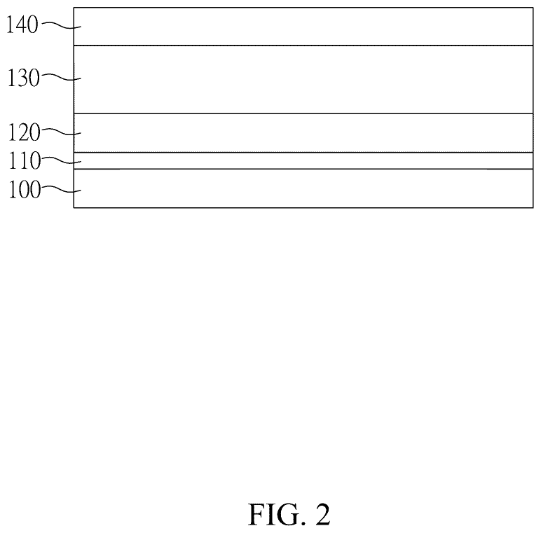

Please refer to FIG. 2, where a second conductive type epitaxial layer 140 is epitaxially grown on the intrinsic epitaxial layer 130. Specifically, this second conductive type epitaxial layer 140 may be, but is not limited to, a P-type indium phosphide (InP) epitaxial layer. This P-type indium phosphide epitaxial layer may be formed using a conventional ion doping and diffusion process or, similarly to the above, using an in-situ doping process with one of zinc (Zn), magnesium (Mg), or beryllium (Be) as the dopant, with a doping concentration of 10¹⁷ to 10¹⁹ cm⁻³.

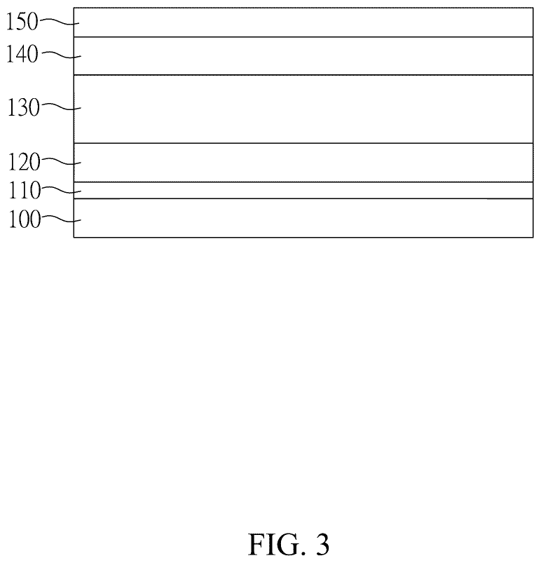

Next, as shown in FIG. 3, an optical bonding layer 150 is grown on the second conductive type epitaxial layer 140. Specifically, the optical bonding layer 150 may be a multi-channel band-pass filter (MBPF) layer configured to allow a light with a specific waveband of the external light to pass therethrough while blocking light of other wavebands from passing through the filter layer. In specific implementations, the composition of the multi-channel band-pass filter layer may be adjusted based on actual filtering waveband requirements, such as, but not limited to, using dielectric materials including silicon oxide (SiOₓ), titanium oxide (TiOₓ), tantalum oxide (Ta₂O₃), and the like. In a preferred implementation, the optical bonding layer 150 further comprises an anti-reflection (AR) layer configured to enhance the passage of light with the specific waveband and reduce surface reflection loss of the optical bonding layer 150.

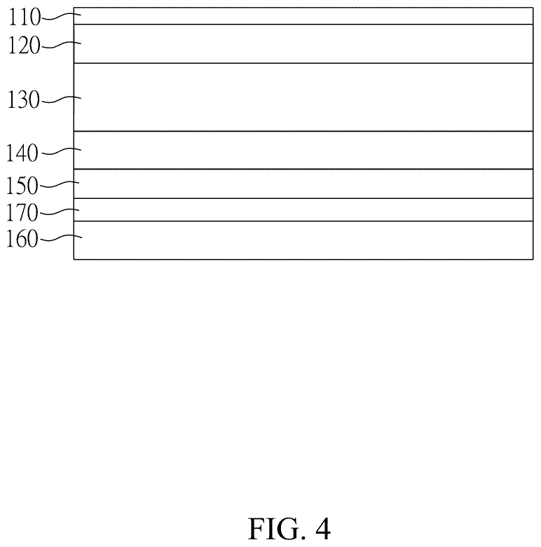

Next, as shown in FIG. 4, a transparent substrate 160 is provided, which may be, but is not limited to, a sapphire substrate. The transparent substrate 160 has a passivation layer 170. Specifically, the passivation layer 170 is selected from the group consisting of silicon oxide, titanium oxide, and combinations thereof, configured to cooperate with the optical bonding layer 150 for wafer transfer and bonding between the epitaxial growth substrate 100 and the transparent substrate 160, such that the passivation layer 170 of the transparent substrate 160 is bonded to the optical bonding layer 150 on the epitaxial growth substrate 100. For example, a chemical solution may be used to treat the surfaces of the optical bonding layer 150 and the passivation layer 170 to form dangling bonds, followed by high-temperature and high-pressure application of van der Waals forces to bond the two wafers to each other. After the optical bonding layer 150 and the passivation layer 170 are bonded, the indium phosphide epitaxial growth substrate 100 is removed through chemical selective etching, with the etching stopping at the indium gallium arsenide (InGaAs) ohmic-contact epitaxial layer 110.

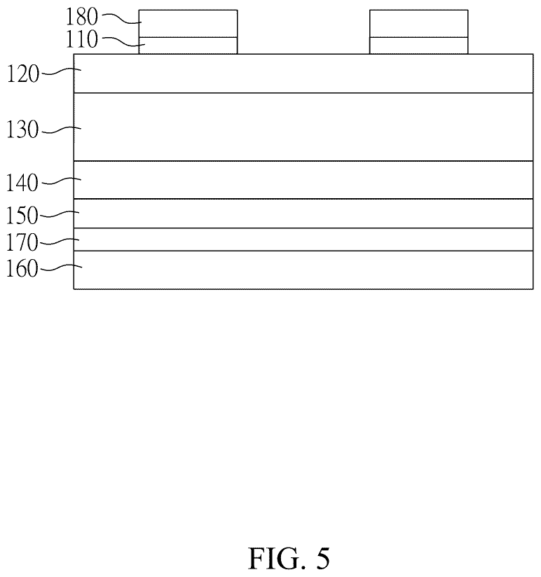

Next, a first conductive type metal layer is formed on the ohmic-contact epitaxial layer 110, and a patterning process is used to etch away portions of the first conductive type metal layer and the ohmic-contact epitaxial layer 110 for forming a first conductive type metal ring 180 and a patterned ohmic-contact epitaxial layer 110 disposed on the upper surface of the first conductive type in-situ doped epitaxial layer 120, as shown in FIG. 5. Specifically, the first conductive type metal ring 180 is an N-type metal material, which may be, but is not limited to, chromium (Cr), palladium (Pd), gold (Au), titanium (Ti), aluminum (Al), silver (Ag), or combinations thereof.

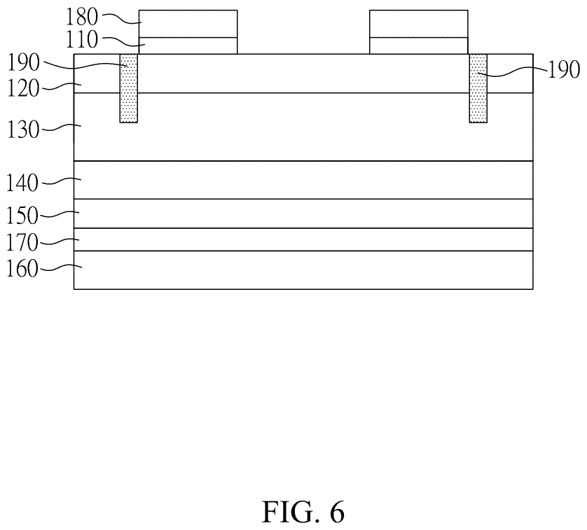

Next, as shown in FIG. 6, to address the issue of low signal-to-noise ratio in photodiodes caused by external light interference, this invention specifically provides a first laser to form a first laser-sintered sidewall 190 using laser sintering, disposed on an outer periphery of the first conductive type in-situ doped epitaxial layer 120, to define an active region and substantially block external light from entering the first conductive type in-situ doped epitaxial layer 120. Specifically, the first laser-sintered sidewall 190 is disposed inside the device sidewall, with the first conductive type metal ring 180 disposed at the inner upper edge of the first laser-sintered sidewall 190, and the first laser-sintered sidewall 190 blocks unintended external light from entering the active region of the device through the device sidewall for preventing subsequent malfunctions. Specifically, a green laser or ultraviolet (UV) laser may be used to form a laser-sintered sidewall with a length of not less than 1 micrometer (μm) at the outer periphery of the first conductive type in-situ doped epitaxial layer 120, to substantially block external light from entering the first conductive type in-situ doped epitaxial layer 120. The length of this first laser-sintered sidewall 190 may be adjusted based on the specifications of the actual flip-chip photodiode device. Preferably, the first laser-sintered sidewall 190 may further be disposed in the intrinsic epitaxial layer to ensure that unintended external light does not enter the diode device through the device sidewall for preventing erroneous noise triggering, while also enhancing the electrostatic protection capability of the flip-chip photodiode.

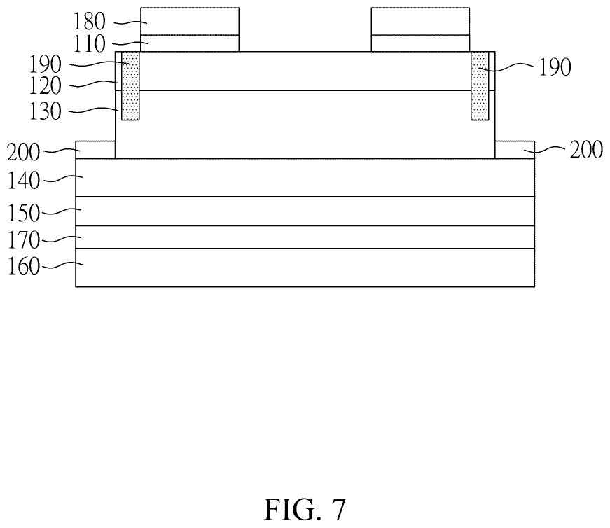

Next, a mesa etching process is performed. Portions of the first conductive type in-situ doped epitaxial layer 120 and the intrinsic epitaxial layer 130 are removed using dry or wet etching to form a mesa epitaxial layer in the flip-chip device structure, as shown in FIG. 7, thereby exposing a portion of the surface of the second conductive type epitaxial layer 140 for use as the position of the second conductive type electrode. Then, a metal process is performed to form a second conductive type metal ring 200 on the exposed surface of the second conductive type epitaxial layer 140 outside the sidewall of the mesa epitaxial layer, and electrically connected to the second conductive type epitaxial layer 140. Specifically, the second conductive type metal ring 200 is a P-type metal material, which may be, but is not limited to, platinum (Pt), palladium (Pd), gold (Au), or combinations thereof.

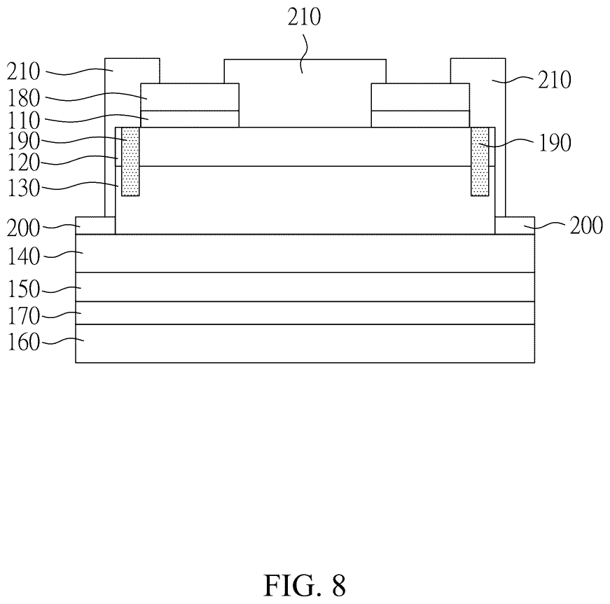

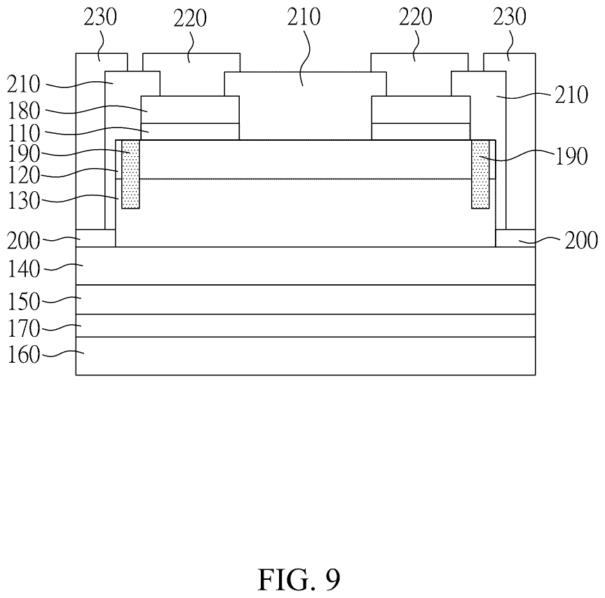

Specifically, to effectively isolate noise interference from the bottom of the flip-chip photodiode device, this invention employs reflector material to replace a traditional protective layer. As shown in FIG. 8, a reflector material deposition process is performed. For example, after depositing a reflector film with a thickness of several thousand angstroms (Å), a patterning process is performed to form a reflector 210 covering the surface and the sidewall of the mesa epitaxial layer, partially covering the first conductive type metal ring 180 and the second conductive type metal ring 200 for leaving portions of the upper surfaces of the first conductive type metal ring 180 and the second conductive type metal ring 200 exposed. That is, it covers only the exposed upper surface of the first conductive type in-situ doped epitaxial layer 120 and the exposed sidewalls of the first conductive type in-situ doped epitaxial layer 120 and the intrinsic epitaxial layer 130, to block external light from entering the mesa epitaxial layer, thereby eliminating external noise interference. Specifically, the reflector 210 may be, but is not limited to, a distributed Bragg reflector (DBR) layer. For example, a reflective film is constructed using silicon oxide and titanium oxide with alternating high and low refractive index layers, achieving strong reflection of light at specific wavelengths due to interference effects between the multilayer interfaces, thereby isolating external noise interference. Next, as shown in FIG. 9, a metal evaporation process is performed to form an N-type metal electrode 220 and a P-type metal electrode 230 on the exposed first conductive type metal ring 180 and second conductive type metal ring 200, respectively, wherein the material of the metal electrodes may be, but is not limited to, a gold-tin alloy.

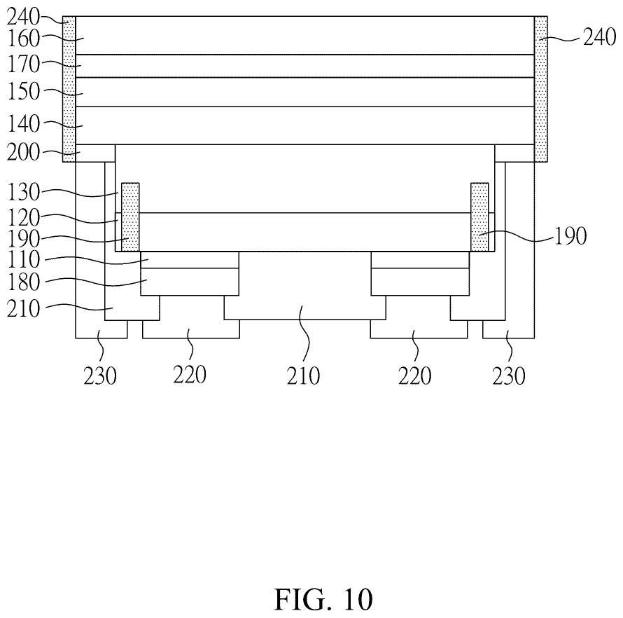

Finally, as shown in FIG. 10, the sapphire substrate is diced to form individual flip-chip photodiode devices. Specifically, a second laser is provided, and laser cutting is used to form a second laser-sintered sidewall 240 on the sidewalls of the transparent substrate 160, the passivation layer 170, the optical bonding layer 150, the second conductive type epitaxial layer 140, and the second conductive type metal ring 200, thereby forming individual flip-chip photodiode devices 10.

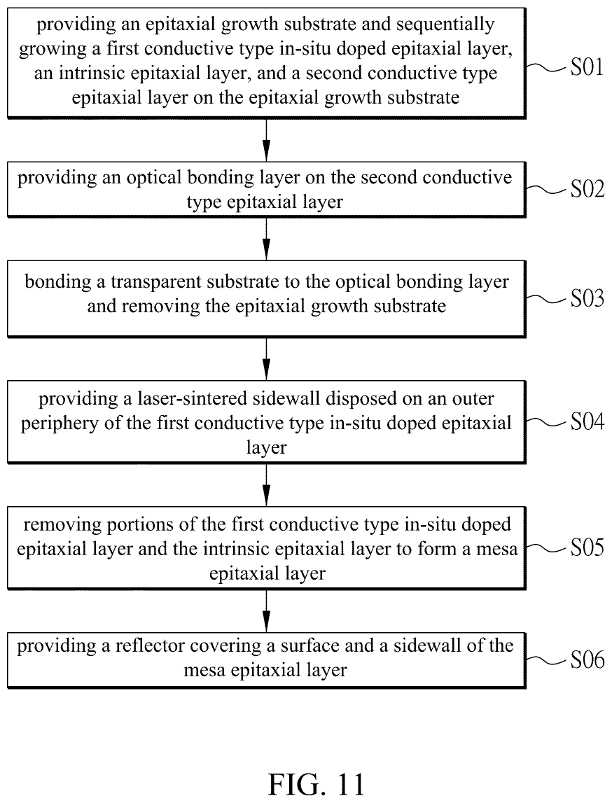

Please refer to FIG. 11, which illustrates a flowchart schematic diagram of the process steps of the flip-chip photodiode of this invention. First, in step S01, an epitaxial growth substrate is provided, and a first conductive type in-situ doped epitaxial layer, an intrinsic epitaxial layer, and a second conductive type epitaxial layer are sequentially grown on the substrate. Next, in step S02, an optical bonding layer is provided on the second conductive type epitaxial layer. In step S03, a transparent substrate is bonded to the optical bonding layer, and the epitaxial growth substrate is removed. In step S04, a laser-sintered sidewall is provided, disposed on an outer periphery of the first conductive type in-situ doped epitaxial layer. In step S05, portions of the first conductive type in-situ doped epitaxial layer and the intrinsic epitaxial layer are removed to form a mesa epitaxial layer. Finally, in step S06, a reflector is provided, covering a surface and a sidewall of the mesa epitaxial layer. The descriptions of the related components can be referred to the above content and will not be repeated here.

As shown in the figures, the flip-chip photodiode 10 of this invention utilizes wafer transfer and bonding technology to transfer the main body of the photodiode device to a high-strength sapphire transparent substrate, addressing the fragility issue of indium phosphide substrates used in traditional SWIR photodiodes, enhancing device structural strength, improving process yield rates, and reducing manufacturing costs to meet the requirements of economical mass production. Furthermore, the flip-chip structure of the photodiode of this invention places both the N-type metal electrode 220 and the P-type metal electrode 230 at the bottom of the device structure, overcoming the drawback of traditional metal wire bonding occupying significant volume, facilitating the miniaturization design of the device by reducing its volume, and increasing device integration. On the other hand, this invention employs several designs to further block external noise interference, thereby improving the signal-to-noise ratio of the device and enhancing photoresponse efficiency to increase current gain. For example, the optical bonding layer 150 disposed below the transparent substrate 160 at the top of the device includes a multi-channel band-pass filter layer configured to allow light with a specific waveband of the external light to pass therethrough while blocking light of other wavebands. Additionally, the optical bonding layer 150 further includes an anti-reflection layer to enhance the passage of light with the specific waveband and reduce surface reflection loss of the optical layer. Furthermore, with respect to the device sidewalls, this invention provides two laser-sintered sidewalls: the first laser-sintered sidewall 190, which prevents noise from entering the active region through the sidewalls, and the outermost second laser-sintered sidewall 240, both of which effectively block noise interference from the device sidewalls. From the perspective of the device bottom, this invention provides a reflector structure to reflect external light, preventing it from entering the interior of the device. In summary, the flip-chip photodiode of this invention incorporates a comprehensive design to prevent noise interference, significantly improving the device's signal-to-noise ratio and enhancing photocurrent gain.

The above embodiments are provided to illustrate the implementations of the present invention and to explain its technical features, and are not intended to limit the scope of the present invention. Any modifications or equivalent arrangements that can be easily accomplished by those skilled in the art fall within the scope of the present invention, and the scope of the present invention should be defined by the claims.

What is claimed is:

1. A flip-chip photodiode, comprising:
a mesa epitaxial layer having an intrinsic epitaxial layer, a first conductive type in-situ doped epitaxial layer, and a laser-sintered sidewall, wherein the intrinsic epitaxial layer is disposed on the first conductive type in-situ doped epitaxial layer, and the laser-sintered sidewall is disposed on an outer periphery of the first conductive type in-situ doped epitaxial layer to substantially block external light from entering the first conductive type in-situ doped epitaxial layer through the laser-sintered sidewall;
a second conductive type epitaxial layer disposed on the mesa epitaxial layer;
a transparent substrate; and
an optical bonding layer bonding the transparent substrate to the second conductive type epitaxial layer, wherein when the external light enters the optical bonding layer through the transparent substrate, only a light with a specific waveband of the external light is allowed to pass therethrough, and other light of the external light other than the specific waveband is blocked.

2. The flip-chip photodiode of claim 1, wherein the laser-sintered sidewall is further disposed in the intrinsic epitaxial layer.

3. The flip-chip photodiode of claim 1, wherein the first conductive type in-situ doped epitaxial layer is an N-type in-situ doped indium phosphide (InP) epitaxial layer, with a dopant selected from one of sulfur (S) or silicon (Si), and a doping concentration of 10¹⁷ to 10¹⁹ cm⁻³.

4. The flip-chip photodiode of claim 1, further comprising a reflector covering the surface and sidewalls of the mesa epitaxial layer to block the external light from entering the mesa epitaxial layer.

5. The flip-chip photodiode of claim 4, wherein the reflector is a distributed Bragg reflector (DBR) layer.

6. The flip-chip photodiode of claim 4, further comprising a first metal ring disposed on the surface of the first conductive type in-situ doped epitaxial layer inside the laser-sintered sidewall and partially covered by the reflector.

7. The flip-chip photodiode of claim 1, further comprising a second metal ring disposed adjacent to the sidewall of the mesa epitaxial layer and electrically connected to the second conductive type epitaxial layer.

8. The flip-chip photodiode of claim 1, wherein the optical bonding layer is a multi-channel band-pass filter (MBPF) layer configured to allow the light with the specific waveband of the external light to pass therethrough.

9. The flip-chip photodiode of claim 8, wherein the optical bonding layer further comprises an anti-reflection (AR) layer configured to reduce surface reflection loss of the optical bonding layer.

10. The flip-chip photodiode of claim 1, wherein the transparent substrate further comprises a passivation layer configured to bond the optical bonding layer for bonding the transparent substrate to the second conductive type epitaxial layer.

11. The flip-chip photodiode of claim 10, wherein the passivation layer is selected from the group consisting of silicon oxide, titanium oxide, and combinations thereof.

12. A manufacturing method for a flip-chip photodiode, comprising:
providing an epitaxial growth substrate and sequentially growing a first conductive type in-situ doped epitaxial layer, an intrinsic epitaxial layer, and a second conductive type epitaxial layer on the epitaxial growth substrate;
providing an optical bonding layer on the second conductive type epitaxial layer;
bonding a transparent substrate to the optical bonding layer and removing the epitaxial growth substrate;
providing a laser-sintered sidewall disposed on an outer periphery of the first conductive type in-situ doped epitaxial layer;
removing portions of the first conductive type in-situ doped epitaxial layer and the intrinsic epitaxial layer to form a mesa epitaxial layer; and
providing a reflector covering a surface and a sidewall of the mesa epitaxial layer.

13. The manufacturing method for a flip-chip photodiode of claim 12, wherein the step of providing a laser-sintered sidewall is to provide a laser to form the laser-sintered sidewall disposed on the outer periphery of the first conductive type in-situ doped epitaxial layer and in the intrinsic epitaxial layer.

14. The manufacturing method for a flip-chip photodiode of claim 12, wherein the step of providing a first conductive type in-situ doped epitaxial layer is to provide an N-type in-situ doped indium phosphide (InP) epitaxial layer.

15. The manufacturing method for a flip-chip photodiode of claim 14, wherein the step of providing an N-type in-situ doped indium phosphide (InP) epitaxial layer is to perform indium phosphide (InP) epitaxial growth using metal-organic chemical vapor deposition (MOCVD) while simultaneously doping with one of sulfur (S) or silicon (Si), with a doping concentration of 10¹⁷ to 10¹⁹ cm⁻³.

16. The manufacturing method for a flip-chip photodiode of claim 12, wherein the step of providing a reflector is to provide a distributed Bragg reflector layer.

17. The manufacturing method for a flip-chip photodiode of claim 12, wherein the method further comprises a step of providing a first metal ring after providing a laser-sintered sidewall, wherein the first metal ring is disposed on the surface of the first conductive type in-situ doped epitaxial layer inside the laser-sintered sidewall.

18. The manufacturing method for a flip-chip photodiode of claim 12, further comprising providing a second metal ring disposed adjacent to the sidewall of the mesa epitaxial layer and electrically connected to the second conductive type epitaxial layer.

19. The manufacturing method for a flip-chip photodiode of claim 12, wherein the step of providing an optical bonding layer is to provide a multi-channel band-pass filter layer configured to allow a light with a specific waveband of the external light to pass therethrough.

20. The manufacturing method for a flip-chip photodiode of claim 19, wherein the step of providing an optical bonding layer further comprises providing an anti-reflection layer configured to reduce surface reflection loss of the optical bonding layer.
